(19) United States
(12) Patent Application Publication
(10) Pub. No.: US 2008/0168331 A1
(43) Pub. Date: Jul. 10, 2008

(54) Memory including error correction code circuit

(76) Inventors: Thomas Vogelsang, Jericho, VT (US); Harald Streif, Burlington, VT (US); Pete Chlumecky, Hinesburg, VT (US); Josef Schnell, Charlotte, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/650,169

(22) Filed: Jan. 5, 2007

(51) Int. Cl. G11C 29/00; G06F 11/07

(52) U.S. Cl. 714/770; 714/E11.021

(57) ABSTRACT

A memory includes an array of memory cells and an error correction code circuit. The error correction code circuit is configured to receive a first portion of a first data word from an external circuit and a second portion of the first data word from the array of memory cells, combine the first portion and the second portion to provide the first data word, and encode the first data word for writing to the array of memory cells.

### BACKGROUND

Memory speed and memory capacity continue to increase to meet the demands of system applications. Some of these system applications include mobile electronic systems that have limited space and limited power resources. In mobile applications, such as cellular telephones and personal digital assistants (PDAs), memory cell density and power consumption are issues for future generations. To address these issues, the industry is developing random access memories (RAMs) for mobile applications. For low power DRAMs, such as low power single data rate (LP-SDR) DRAMs and low power double data rate (LP-DDR) DRAMs, reducing the refresh current is one way to reduce power consumption.

To reduce the refresh current, the refresh period is typically extended. Extending the refresh period, however, typically results in some memory cells failing due to the extended refresh period. For example, 99.9% of the memory cells in an array of memory cells may have a retention time of 250 ms. The other 0.1%, however, may fail to retain their values from anywhere between approximately 0-200 ms. These memory cells that fail to retain their values are referred to as tail bits. These tail bits may lead to single bit errors during self refresh of a memory. By detecting and correcting for these tail bits, the refresh period may be extended to reduce the refresh current.

Error correction code (ECC) calculates parity information and can determine if a bit has switched to an incorrect value. ECC can compare the parity originally calculated to the tested parity and make any corrections to correct for incorrect data values. In some cases, it is desirable to have ECC built directly onto a memory chip to provide greater memory chip reliability or to optimize other memory chip properties such as self refresh currents on low power DRAMs. ECC circuitry, however, is typically associated with a large overhead due to additional memory elements used to store the parity information. Typical ECC implementations may cost up to 50% of the memory chip area.

A typical low power DRAM has many options which require different data widths to be retrieved from the array or to be written to the array (e.g., different organizations such as x16 or x32, different interface standards such as SDR or DDR, and data masking in these organizations and standards). Reading data from and writing data to a memory array with ECC should be performed at high speed. In addition, the ECC should use as little memory array overhead as possible to save chip area. An ECC code gets more efficient as the data word to be corrected gets longer because the number of parity bits used to correct one bit in the data word rises logarithmically with word length. Therefore, the percentage of parity memory cells in the memory array decreases with rising data word length. If the ECC word length used is longer than the number of bits provided by an external circuit during a write operation, then the new parity has to be calculated by combining bits already in the memory array with the bits provided by the external circuit. The combining of bits turns the write operation into a read-modify-write operation.

Typical memories avoid a read-modify-write operation by using the smallest data word length out of all required data word lengths as the basic data word that is corrected by ECC. Since data masking is done by byte in a typical DRAM specification, an ECC array overhead of at least 50% is required (the smallest overhead code to correct one bit out of eight is a Hamming code, which uses four parity bits). With a typical DRAM architecture, a read-modify-write operation is not possible at speed since there would be data contention on the bidirectional array data lines. This is especially the case when considering the delay created by the ECC data correction logic.

For these and other reasons, there is a need for the present invention.

### SUMMARY

One embodiment provides a memory. The memory includes an array of memory cells and an error correction code circuit. The error correction code circuit is configured to receive a first portion of a first data word from an external circuit and a second portion of the first data word from the array of memory cells, combine the first portion and the second portion to provide the first data word, and encode the first data word for writing to the array of memory cells.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a memory device.

FIG. 2 is a block diagram illustrating one embodiment of a read-modify-write operation.

FIG. 3 is a timing diagram illustrating one embodiment of the timing of signals for a read-modify-write operation for the memory device.

FIG. 4 is a block diagram illustrating one embodiment of a circuit for a DDR SDRAM.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

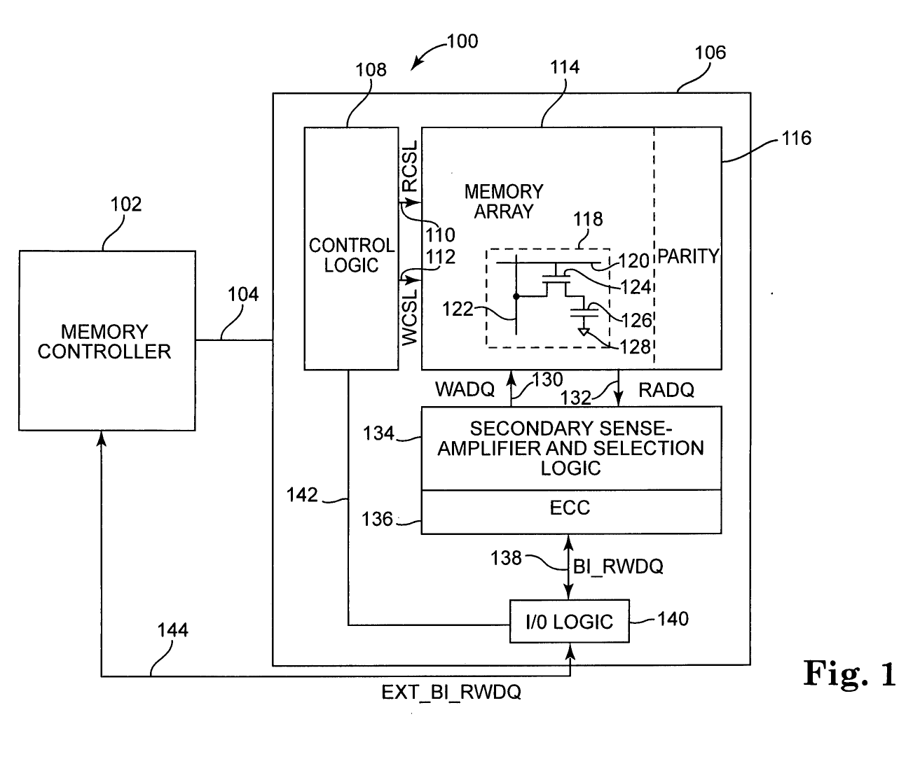

FIG. 1 is a block diagram illustrating one embodiment of a memory device 100. Memory device 100 includes a memory controller 102 and a memory 106. Memory controller 102 is electrically coupled to memory 106 through memory communications path 104 and external bidirectional read/write data lines (EXT_BI_RWDQ) 144. Memory 106 includes control logic 108, a memory array 114, secondary sense-amplifier and selection logic 134, an error correction code (ECC) circuit 136, and input/output (I/O) logic 140. In one embodiment, memory device 100 is a single data rate (SDR) dynamic random access memory (DRAM). In another embodiment, memory device 100 is a double data rate (DDR) DRAM.

As used herein, the term “electrically coupled” is not meant to mean that the elements must be directly coupled together and intervening elements may be provided between the “electrically coupled” elements.

Control logic 108 is electrically coupled to memory array 114 through read column select lines (RCSL) 110 and write column select lines (WCSL) 112. Memory array 114 includes a plurality of memory cells 118 for storing data and a plurality of memory cells 118 (i.e., parity memory) for storing parity data as indicated at 116. Memory array 114 is electrically coupled to secondary sense-amplifier and selection logic 134 through write array data lines (WADQ) 130 and read array data lines (RADQ) 132. Secondary sense-amplifier and selection logic 134 is electrically coupled to ECC circuit 136. ECC circuit 136 is electrically coupled to I/O logic 140 through bidirectional read/write data lines (BI_RWDQ) 138. I/O logic 140 is electrically coupled to control logic 108 through signal path 142 and to memory controller 102 through external bidirectional read/write data lines 144.

In memory device 100, the column select lines between control logic 108 and memory array 114 are separated to provide read column select lines 110 for selecting memory cells for read operations and write column select lines 112 for selecting memory cells for write operations. In addition, the data lines between memory array 114 and secondary sense-amplifier and selection logic 134 are also separated to provide write array data lines 130 to pass data to memory array 114 during write operations and read array data lines 132 to pass data from memory array 114 during read operations. The bidirectional read/write data lines 138 between ECC circuit 136 and I/O logic 140 and the external bidirectional read/write data lines 144 between I/O logic 140 and memory controller 102 are shared data lines for both passing data from memory 106 during read operations and for passing data to memory 106 during write operations.

By having separate column select lines and separate array data lines for read and write operations, data can be read from and written to memory array 114 simultaneously. By being able to simultaneously read data from and write data to memory array 114, an ECC operation is performed at speed using larger ECC words than possible with typical memory devices. Larger ECC words use fewer parity bits than smaller EEC words, therefore memory device 100 uses less chip area to store parity data compared to typical DRAMs.

Memory controller 102 controls the operation of memory 106. Memory controller 102 includes a microprocessor, microcomputer, or other suitable logic circuitry for controlling the operation of memory 106 through memory communications path 104. Memory controller 102 provides clock signals, command signals, and other signals to control logic 108, secondary sense-amplifier and selection logic 134, and ECC circuit 136 for reading data from and writing data to memory array 114. Memory controller 102 provides data to write to memory 106 and receives data read from memory 106 through I/O logic 140 and external bidirectional read/write data lines 144. Memory controller 102 receives data to write to memory 106 from a host or external circuit (not shown). Memory controller 102 also provides data read from memory 106 to the host or external circuit.

Control logic 108 provides write column select signals to memory array 114 through write column select lines 112 and read column select signals to memory array 114 through read column select lines 110. Write column select signals are provided to memory array 114 to access memory cells for writing data to the memory cells. Read column select signals are provided to memory array 114 to access memory cells for reading data from the memory cells. Control logic 108 also controls I/O logic 140 through signal path 142 to control the timing and passing of data between bidirectional read/write data lines 138 and external bidirectional read/write data lines 144.

Memory array 114 includes a plurality of memory cells 118 for storing data and parity information. In one embodiment, each memory cell 118 includes a transistor 124 and a capacitor 126. The gate of transistor 124 is electrically coupled to a word line 120. One side of the drain-source path of transistor 124 is electrically coupled to a bit line 122 and the other side of the drain-source path is electrically coupled to one side of capacitor 126. The other side of capacitor 126 is electrically coupled to a reference 128, such as one-half the supply voltage or ground. Capacitor 126 is charged and discharged to represent a logic “0” or a logic “1”. In other embodiments, other suitable memory cell elements and structures are used.

During a read operation, word line 120 is activated to turn on transistor 124 and the data bit value stored on capacitor 126 is read by a sense amplifier through bit line 122. During a write operation, word line 120 is activated to turn on transistor 124 and access capacitor 126. The sense amplifier connected to bit line 122 is overdriven to write a data bit value on capacitor 126 through bit line 122 and transistor 124.

A read operation on memory cell 118 is a destructive read operation. After each read operation, capacitor 126 is recharged or discharged to the data bit value that was just read. In addition, even without read operations, the charge on capacitor 126 discharges over time. To retain a stored data bit value, memory cell 118 is refreshed periodically by reading and/or writing memory cell 118 such as during self refresh. All memory cells 118 in array of memory cells 114 are periodically refreshed to maintain their values.

Parity memory 116 stores parity information for data words stored in memory cells 118 within memory array 114. For example, if using a Hamming code and eight bit data words, parity memory 116 stores four parity bits for each data word. For 64 bit data words, parity memory 116 stores eight parity bits for each data word. The number of parity bits for each data word varies depending on the length of the data word and the particular ECC method used. As the length of the data word increases, the total number of parity bits stored in parity memory 116 for memory array 114 decreases.

Secondary sense-amplifier and selection logic 134 writes data to memory array 114 through write array data lines 130. Secondary sense-amplifier and selection logic circuit 134 reads data from memory array 114 through read array data lines 132. ECC circuit 136 receives data from I/O logic 140 on bidirectional read/write data lines 138 to encode and write to memory array 114. ECC circuit 136 receives read data from memory array 114 to decode and correct if an error is detected. The decoded and corrected data is provided to I/O logic 140 on bidirectional read/write data lines 138.

If the data from I/O logic 140 to be written to memory array 114 is masked such that the data includes fewer bytes than the ECC word size for storing data in memory array 114, ECC circuit 136 receives the data for the masked data byte or bytes for the ECC word from memory array 114. ECC circuit 136 decodes the data byte or bytes from memory array 114 and then combines the decoded data from memory array 114 with the data from I/O logic 140. The combined data is then encoded by ECC circuit 136 and written to memory array 114. In this way, a write operation in which one or more data bytes have been masked is replaced with a read-modify-write operation. The read-modify-write operation is completed at speed for both a SDR DRAM and a DDR DRAM.

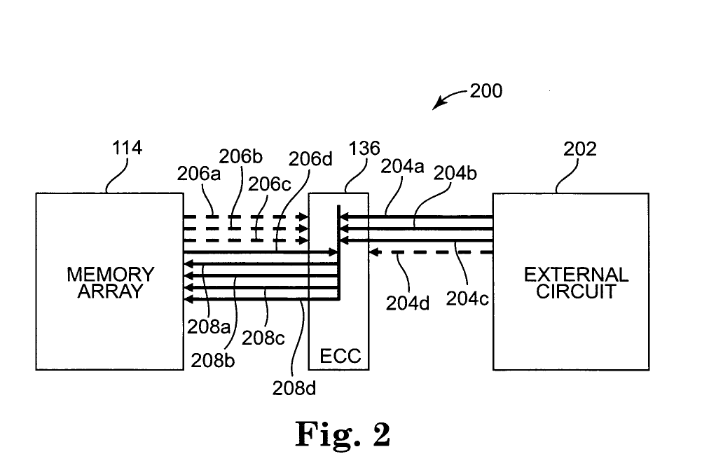

FIG. 2 is a block diagram illustrating one embodiment of a read-modify-write operation 200. Read-modify-write operation 200 involves memory array 114, ECC circuit 136, an external circuit 202, and other related circuitry (not shown). In this embodiment, the ECC word length is four bytes (i.e., 32 bits). In other embodiments, different ECC word lengths such as two bytes or eight bytes can be used. During a write operation, external circuit 202 provides three data bytes as indicated by 204a-204c to ECC circuit 136. In this embodiment, one data byte as indicated by 204d has been masked. Since ECC circuit 136 has an ECC word length of 32 bits, ECC circuit 136 receives the data for the masked byte 204d from memory array 114 as indicated by 206d in response to the read portion of the read-modify-write operation. The other unmasked bytes as indicated by 206a-206c for the ECC word from memory array 114 are not used since they are provided by external circuit 202.

ECC circuit 136 decodes byte 206d from memory array 114 and corrects the data if an incorrect data bit is detected. The decoded byte 206d is combined with bytes 204a-204c from external circuit 202 to form a complete data word for encoding during the modify portion of the read-modify-write operation. ECC circuit 136 then encodes the complete data word. The encoded data word bytes are then written to memory array 114 as indicated by 208a-208d in response to the write portion of the read-modify-write operation. In other embodiments, two or three of bytes 204a-204d can be masked. In any case, the data for the masked bytes is read from memory array 114 and combined with the unmasked bytes from external circuit 202.

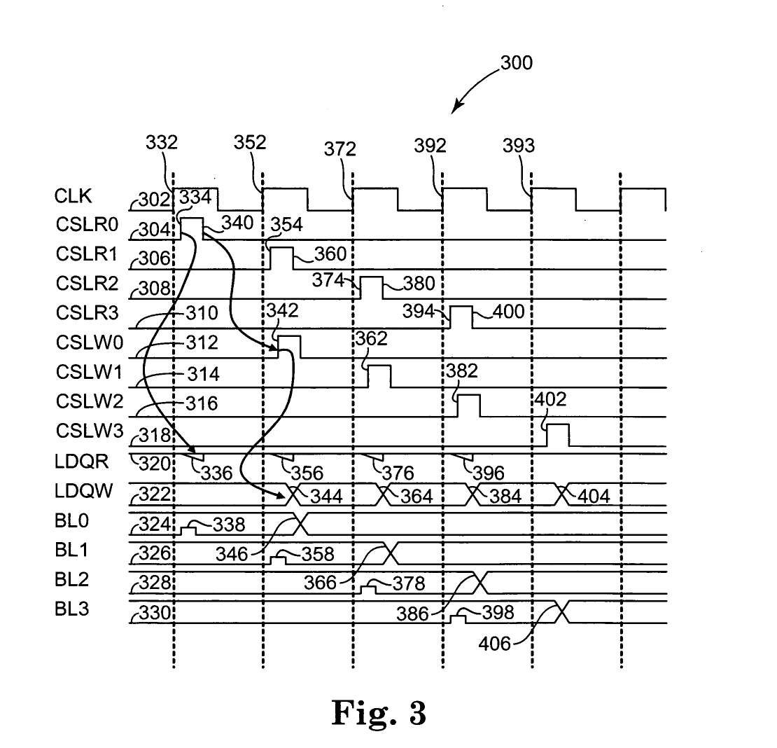

FIG. 3 is a timing diagram 300 illustrating one embodiment of the timing of signals for a read-modify-write operation for memory device 100. Timing diagram 300 includes a clock (CLK) signal 302 on memory communications path 104, a first column select line read (CSLR0) signal 304 on read column select lines 110, a second column select line read (CSLR1) signal 306 on read column select lines 110, a third column select line read (CSLR2) signal 308 on read column select lines 110, and a fourth column select line read (CSLR3) signal 310 on read column select lines 110. Timing diagram 300 also includes a first column select line write (CSLW0) signal 312 on write column select lines 112, a second column select line write (CSLW1) signal 314 on write column select lines 112, a third column select line write (CSLW2) signal 316 on write column select lines 112, and a fourth column select line write (CSLW3) signal 318 on write column select lines 112. Timing diagram 300 also includes a local data line read (LDQR) signal 320 on read array data lines 132, a local data line write (LDQW) signal 322 on write array data lines 130, a first bit line (BL0) signal 324 on a first bit line 122, a second bit line (BL1) signal 326 on a second bit line 122, a third bit line (BL2) signal 328 on a third bit line 122, and a fourth bit line (BL3) signal 330 on a fourth bit line 122.

Timing diagram 300 illustrates read-modify-write operations for a burst length of four. In other embodiments, other suitable burst lengths are used. Each read-modify-write operation illustrated reads and writes to an individual memory cell 118. Multiple signals similar to the signals illustrated in timing diagram 300 are used in parallel to read and write a plurality of memory cells 118 based on the ECC word length.

At rising edge 332 of CLK signal 302, the read portion of the first read-modify-write operation for a first bit in the burst is initiated. In response to the read portion, CSLR0 signal 304 transitions to logic high at 334 to select a first memory cell for read access. The first memory cell stores a data bit to use in place of a masked data bit not provided by the external circuit. In response to rising edge 334 of CSLR0 signal 304, the data bit value is read as indicated at 338 on BL0 signal 324. The data bit value is passed from the first bit line to secondary sense-amplifier and selection logic 134 on read array data lines 132 as indicated at 336 on LDQR signal 320. After the data bit value has been read, CSLR0 signal 304 transitions to logic low at 340.

Between falling edge 340 of CSLR0 signal 304 and rising edge 342 of CSLW0 signal 312, the modify portion of the first read-modify-write operation of the burst is performed. During this time, ECC circuit 136 combines the data received from the external circuit with the data received from memory array 114 and encodes the combined data to provide a first encoded data word. The length of this modify portion varies based on whether the memory is a SDR DRAM or a DDR DRAM and the ECC correction time.

The write portion of the first read-modify-write operation of the burst is initiated after the next rising edge 352 of CLK signal 302. In response to the write operation, CSLW0 signal 312 transitions to logic high at 342 to select the first memory cell for write access. In response to rising edge 342 of CSLW0 signal 312, secondary sense-amplifier and selection logic 134 provides the data bit on write array data lines 130 as indicated at 344 on LDQW signal 322. The data bit indicated at 344 on LDQW signal 322 is passed to the first bit line as indicated at 346 on BL0 signal 324. The data bit is stored in the first memory cell. The first memory cell now stores a data bit of the first encoded data word.

At the same time the data bit is being written to the first memory cell as indicated at 346 of BL0 signal 324, the read operation for the following data bit in the burst is occurring. At rising edge 352 of CLK signal 302, the read portion of a second read-modify-write operation for the second bit in the burst is initiated. In response to the read portion, CSLR1 signal 306 transitions to logic high at 354 to select a second memory cell for read access. The second memory cell stores a data bit to use in place of a masked data bit not provided by the external circuit. In response to rising edge 354 of CSLR1 signal 306, the data bit value is read as indicated at 358 on BL1 signal 326. The data bit value is passed from the second bit line to secondary sense-amplifier and selection logic 134 on read array data lines 132 as indicated at 356 on LDQR signal 320. After the data bit value has been read, CSLR1 signal 306 transitions to logic low at 360. Therefore, data is written to a first memory cell within memory array 114 as indicated at 346 on BL0 signal 324 substantially simultaneously with data being read from a second memory cell within memory array 114 as indicated at 358 on BL1 signal 326. In this way, memory device 100 can operate at speed during a read-modify-write operation.

Between falling edge 360 of CSLR1 signal 306 and rising edge 362 of CSLW1 signal 314, the modify portion of the second read-modify-write operation of the burst is performed. During this time, ECC circuit 136 combines the data received from the external circuit with the data received from memory array 114 and encodes the combined data to provide a second encoded data word.

The write portion of the second read-modify-write operation of the burst is initiated after the next rising edge 372 of CLK signal 302. In response to the write operation, CSLW1 signal 314 transitions to logic high at 362 to select the second memory cell for write access. In response to rising edge 362 of CSLW1 signal 314, secondary sense-amplifier and selection logic 134 provides the data bit on write array data lines 130 as indicated at 364 on LDQW signal 322. The data bit at 364 on LDQW signal 322 is passed to the second bit line as indicated at 366 on BL1 signal 326. The data bit is stored in the second memory cell. The second memory cell now stores a data bit of the second encoded data word.

At the same time the data bit is being written to the second memory cell as indicated at 366 of BL1 signal 326, the read operation for the following data bit in the burst is occurring. At rising edge 372 of CLK signal 302, the read portion of a third read-modify-write operation for the third bit in the burst is initiated. In response to the read operation, CSLR2 signal 308 transitions to logic high at 374 to select a third memory cell for read access. The third memory cell stores a data bit to use in place of a masked data bit not provided by the external circuit. In response to rising edge 374 of CSLR2 signal 308, the data bit value is read as indicated at 378 on BL2 signal 328. The data bit value is passed from the third bit line to secondary sense-amplifier and selection logic 134 on read array data lines 132 as indicated at 376 on LDQR signal 320. After the data bit value has been read, CSLR2 signal 308 transitions to logic low at 380. Therefore, data is written to a second memory cell within memory array 114 as indicated at 366 on BL1 signal 326 substantially simultaneously with data being read from a third memory cell within memory array 114 as indicated at 378 on BL2 signal 328.

Between falling edge 380 of CSLR2 signal 308 and rising edge 382 of CSLW2 signal 316, the modify portion of the third read-modify-write operation of the burst is performed. During this time, ECC circuit 136 combines the data received from the external circuit with the data received from memory array 114 and encodes the combined data to provide a third encoded data word.

The write portion for the third read-modify-write operation of the burst is initiated after the next rising edge 392 of CLK signal 302. In response to the write operation, CSLW2 signal 316 transitions to logic high at 382 to select the third memory cell for write access. In response to rising edge 382 of CSLW2 signal 316, secondary sense-amplifier and selection logic 134 provides the data bit on write array data lines 130 as indicated at 384 on LDQW signal 322. The data bit at 384 on LDQW signal 322 is passed to the third bit line as indicated at 386 on BL2 signal 328. The data bit is stored in the third memory cell. The third memory cell now stores a data bit of the third encoded data word.

At the same time the data bit is being written to the third memory cell as indicated at 386 of BL2 signal 328, the read operation for the following data bit in the burst is occurring. At rising edge 392 of CLK signal 302, the read portion of a read-modify-write operation for the fourth bit in the burst is initiated. In response to the read operation, CSLR3 signal 310 transitions to logic high at 394 to select a fourth memory cell for read access. The fourth memory cell stores a data bit to use in place of a masked data bit not provided by the external circuit. In response to rising edge 394 of CSLR3 signal 310, the data bit value is read as indicated at 398 on BL3 signal 330. The data bit value is passed from the fourth bit line to secondary sense-amplifier and selection logic 134 on read array data lines 132 as indicated at 396 on LDQR signal 320. After the data bit value has been read, CSLR3 signal 310 transitions to logic low at 400. Therefore, data is written to a third memory cell within memory array 114 as indicated at 386 on BL2 signal 328 substantially simultaneously with data being read from a fourth memory cell within memory array 114 as indicated at 398 on BL3 signal 330.

Between falling edge 400 of CSLR3 signal 310 and rising edge 402 of CSLW3 signal 318, the modify portion of the fourth read-modify-write operation of the burst is performed. During this time, ECC circuit 136 combines the data received from the external circuit with the data received from memory array 114 and encodes the combined data to provide a fourth encoded data word.

The write portion for the fourth read-modify-write operation of the burst is initiated after the next rising edge 393 of CLK signal 302. In response to the write operation, CSLW3 signal 318 transitions to logic high at 402 to select the fourth memory cell for write access. In response to rising edge 402 of CSLW3 signal 318, secondary sense-amplifier and selection logic 134 provides the data bit on write array data lines 322 as indicated at 404 on LDQW signal 322. The data bit at 404 on LDQW signal 322 is passed to the fourth bit line as indicated at 406 on BL3 signal 330. The data bit is stored in the fourth memory cell. The fourth memory cell now stores a data bit of the fourth encoded data word.

In the illustrated embodiment of timing diagram 300, the delays between the column select line read signals and the column select line write signals were derived from the edges of CLK signal 302. In other embodiments, however, an internal timer circuit is used to provide the edges in place of the edges of CLK signal 302 to derive the delays between the column select line read signals and the column select line write signals. In one embodiment, where memory device 100 is a DDR DRAM, the delays between the column select line read signals and the column select line write signals are derived from the edges of CLK signal 302. In one embodiment, where memory device 100 is a SDRAM, the delays between the column select line read signals and the column select line write signals are derived from the edges of an internal timer circuit.

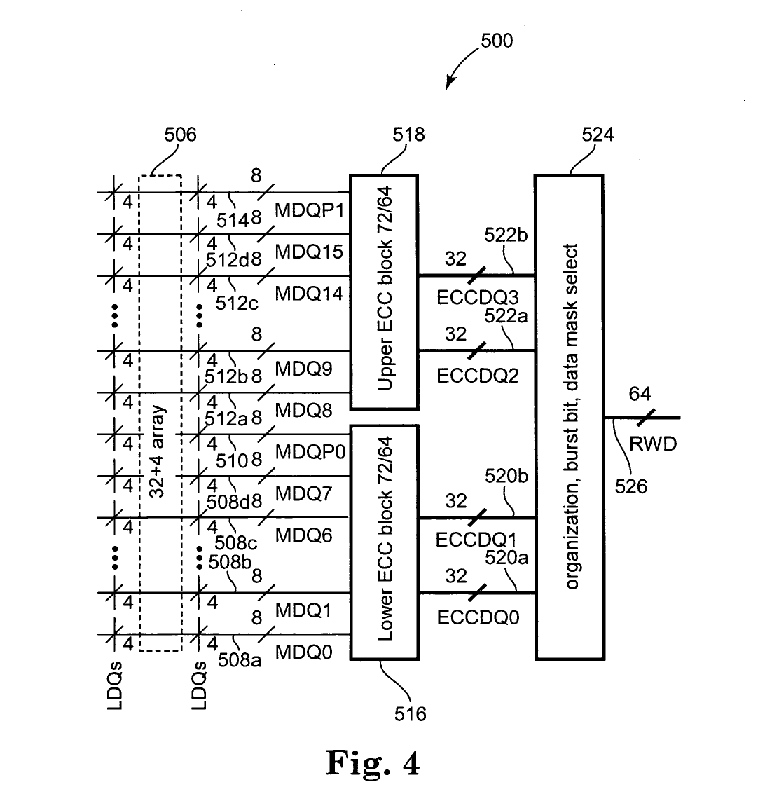

FIG. 4 is a block diagram illustrating one embodiment of a circuit 500 for a DDR DRAM. For SDR DRAM, the burst type does not create any issues. For SDR DRAM, one set of data is required per clock cycle and control circuitry can order the addresses and data correctly with the core frequency of the SDR DRAM. For DDR DRAM, however, the core frequency is half the data rate. The core of the DDR DRAM therefore uses a two bit prefetch to provide two bits of data in parallel per bit of serial data output (e.g., 64 bits for a x32 DDR interface).

Interleaved bursts and sequential bursts with even start addresses combine data from burst addresses zero and one, two and three, four and five, etc., on the rising and falling clock edges respectively. Sequential bursts with odd start addresses, however, combine data from burst addresses one and two, three and four, five and six, etc. If the ECC word combines data from addresses for one allowed burst sequence but not for another then two ECC words are evaluated simultaneously. The requested bits are then combined and the other bits are discarded. For example, one ECC word includes data from burst addresses zero and one and another ECC word includes data from burst addresses two and three. If both burst addresses one and two are requested, both ECC words are simultaneously selected and decoded. The data bits from burst addresses one and two are used and the data bits from burst addresses zero and three are discarded. FIG. 4 illustrates one embodiment of two ECC blocks for enabling this process in a DDR DRAM.

Circuit 500 includes a memory array 506, a lower ECC block 516, an upper ECC block 518, and an organization, burst bit, and data mask select circuit 524. In this embodiment, the ECC word is 64 bits and eight parity bits are used for each ECC word. In other embodiments, other suitable ECC word lengths with their corresponding number of parity bits are used.

Lower ECC block 516 is electrically coupled to memory array 506 through local data line (LDQs), master data lines (MDQs) 508a-508d, and first master parity data lines (MDQP0) 510. Lower ECC block 516 is electrically coupled to organization, burst bit, and data mask select circuit 524 through first error correction code data lines (ECCDQ0) 520a and second error correction code data lines (ECCDQ1) 520b. Upper ECC block 518 is electrically coupled to memory array 506 through local data line (LDQs), master data lines (MDQs) 512a-512d, and second master parity data lines (MDQP1) 514. Upper ECC block 518 is electrically coupled to organization, burst bit, and data mask select circuit 524 through third error correction code data lines (ECCDQ2) 522a and fourth error correction code data lines (ECCDQ3) 522b. Organization, burst bit, and data mask select circuit 524 is electrically coupled to an external circuit through read/write data lines (RWD) 526. For simplicity, circuit 500 illustrates only one set of LDQs and MDQs, however, the LDQs and MDQs are doubled to provide one set for read operations and one set for write operations.

Lower ECC block 516 receives 64 bit data words through MDQ0-MDQ7 data lines and associated eight parity bits through MDQP0 parity data lines. Lower ECC block 516 decodes each 64 bit data word and corrects any failed bits if an error is detected. A first half of each decoded data word is output on ECCDQ0 520a and a second half of each decoded data word is output on ECCDQ1 520b.

Upper ECC block 518 receives 64 bit data words through MDQ8-MDQ15 data lines and associated eight parity bits through MDQP1 parity data lines. Upper ECC block 518 decodes each 64 bit data word and corrects any failed bits if an error is detected. A first half of each decoded data word is output on ECCDQ2 522a and a second half of each decoded data word is output on ECCDQ3 522b.

During a read operation, lower ECC block 516 receives an encoded data word and the parity information for the encoded data word from memory array 506. The encoded data word is decoded and corrected if an error is detected and passed to organization, burst bit, and data mask select circuit 524 through ECCDQ0 520a and ECCQD1 520b. Upper ECC block 518 receives an encoded data word and the parity information for the encoded data word from memory array 506. The encoded data word is decoded and corrected if an error is detected and passed to organization, burst bit, and data mask select circuit 524 through ECCDQ2 522a and ECCQD3 522b. Organization, burst bit, and data mask select circuit 524 selects the 64 bits of data passed from lower ECC block 516, the 64 bits of data passed from upper ECC block 518, or 32 bits of data from lower ECC block 516 and 32 bits of data from upper ECC block 518 to provide the 64 bit data word on RWD 526.

Embodiments of the present invention provide a memory device using ECC with ECC words including more bits than provided from an external circuit for writing to the memory array. Longer ECC words improve chip size efficiency over shorter ECC words. If the ECC word size of a DRAM with ECC is longer than the shortest word used in the write operation of the DRAM, then data from the memory array is combined with external data to calculate the parity in a read-modify-write operation. A read-modify-write operation is performed at sufficient speed using separate read array data lines and write array data lines and read column select lines and write column select lines to meet the timing specifications for SDR DRAM and DDR DRAM.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory comprising:
an array of memory cells; and
an error correction code circuit configured to receive a first portion of a first data word from an external circuit and a second portion of the first data word from the array of memory cells, combine the first portion and the second portion to provide the first data word, and encode the first data word for writing to the array of memory cells.

2. The memory of claim 1, further comprising:
read data lines for passing the second portion of the first data word from the array of memory cells to the error correction code circuit; and
write data lines for passing the encoded first data word from the error correction code circuit to the array of memory cells.

3. The memory of claim 1, further comprising:
read column select lines for selecting memory cells within the array of memory cells for read access; and
write column select lines for selecting memory cells within the array of memory cells for write access.

4. The memory of claim 1, further comprising:
a data select circuit;
wherein the error correction code circuit comprises:
a first error correction code block configured to decode a second data word and pass the decoded second data word to the data select circuit; and
a second error correction code block configured to decode a third data word and pass the decoded third data word to the data select circuit;
wherein the data select circuit is configured to select one of the decoded second data word, the decoded third data word, and a portion of the decoded second data word and a portion of the decoded third data word to pass to the external circuit.

5. The memory of claim 1, wherein the memory comprises a single data rate dynamic random access memory.

6. The memory of claim 1, wherein the memory comprises a double data rate dynamic random access memory.

7. A memory comprising:
an array of memory cells;
read data lines for reading data from the array of memory cells;
write data lines for writing data to the array of memory cells; and
an error correction code circuit configured to receive external data to be written to the array of memory cells, combine the external data with data read from the array of memory cells, and encode the combined data for writing to the array of memory cells.

8. The memory of claim 7, further comprising:
read column select lines for selecting memory cells within the array of memory cells for read access; and
write column select lines for selecting memory cells within the array of memory cells for write access.

9. The memory of claim 8, wherein the write column select lines are for selecting first memory cells within the array of memory cells for write access simultaneously with the read column select lines selecting second memory cells within the array of memory cells for read access.

10. The memory of claim 7, further comprising:
bidirectional read/write data lines for passing data between the error correction code circuit and an input/output circuit.

11. The memory of claim 7, wherein the memory comprises a single data rate dynamic random access memory.

12. The memory of claim 7, wherein the memory comprises a double data rate dynamic random access memory.

13. A memory comprising:
an array of memory cells;
means for simultaneously writing data to the array of memory cells and reading data from the array of memory cells; and
means for encoding a data word including at least one byte from an external circuit and at least one byte from the array of memory cells.

14. The memory of claim 13, wherein the at least one byte from the array of memory cells comprises at least one masked byte not provided by the external circuit.

15. The memory of claim 13, wherein the data word comprises at least 16 bits.

16. The memory of claim 13, wherein the memory comprises a single data rate dynamic random access memory.

17. The memory of claim 13, wherein the memory comprises a double data rate dynamic random access memory.

18. A method for writing to a memory, the method comprising:
receiving first external data from an external circuit;
reading first data from a memory array through a first data path;
combining the first external data with the first data read from the memory array;
encoding the combined data; and
writing the encoded combined data to the memory array through a second data path.

19. The method of claim 18, further comprising:
receiving second external data from the external circuit; and
reading second data from the memory array through the first data path simultaneously with writing the encoded combined data to the memory array through the second data path.

20. The method of claim 18, further comprising:
decoding the first data from the memory array.

21. The method of claim 20, further comprising:
correcting the first data from the memory array in response to detecting an error.

22. The method of claim 18, wherein receiving the first external data comprises receiving the first external data at a single data rate.

23. The method of claim 18, wherein receiving the first external data comprises receiving the first external data at a double data rate.

24. A method for accessing a memory, the method comprising:
receiving a first portion of a data word from an external circuit;
receiving a second portion of the data word from an array of memory cells;
combining the first portion and the second portion to provide the data word;
encoding the data word; and
writing the encoded data word to the array of memory cells.

25. The method of claim 24, wherein receiving the second portion comprises receiving the second portion through first data lines, and
wherein writing the encoded data word comprises writing the encoded data word through second data lines.

26. The method of claim 24, further comprising:
selecting first memory cells for read access with first select lines for receiving the second portion; and
selecting second memory cells for write access with second select lines for writing the encoded data word.

27. The method of claim 24, further comprising:
reading a first data word from the array of memory cells;
decoding the first data word;
reading a second data word from the array of memory cells;
decoding the second data word; and
passing one of the first data word, the second data word, and a portion of the first data word and a portion of the second data word to the external circuit.
